(19) United States
(12) Patent Application Publication
(10) Pub. No.: US 2012/0312233 A1
(43) Pub. Date: Dec. 13, 2012

(54) Magnetically Enhanced Thin Film Coating Method and Apparatus

(76) Inventors: Ge Yi, San Ramon, CA (US); Yunjun Tang, Pleasanton, CA (US)

(21) Appl. No.: 13/157,312

(22) Filed: Jun. 10, 2011

(51) Int. Cl. C23C 16/503; C23C 16/507

(52) U.S. Cl. 118/723 MP; 118/723 R

(57) ABSTRACT

Methods and apparatuses for implementing magnetic field to assist PECVD to locally or globally coat the internal surface of the work piece are presented. Several permanent magnet assembly designs have been presented to provide efficient and effective magnetic field inside the work piece, which acts partially as the working chamber. The magnet assembly generates magnetic flux inside the working chamber, which increases the efficiency of PECVD process, enable PECVD process under higher gas pressure and to improve the uniformity, deposition rate, better adhesion and reduce the process temperature.

### REFERENCE CITED

### Us Patent Documents

1) K. Baba et.al, Surface and Coating Technology, Vol. 74-75, 1995, P292.
2) Hitomi Yamaguchi, et.al, J. Manufacturing Science and Engineering, Vol. 129, 2007, P885.
3) Hiroyuki Yoshiki, et.al, J. Vac. Sci. A 26(3), May/June 2008, P338;
4) Hiroyuki Yoshiki, et.al, Vacuum 84 (2010)559;
5) Shamim M. Malik, et.al, J. Vac. Sci. A 15(6), November/December 1997, P2875;
6) R. Hytry, et.al, Surface and Coating Technology, 74-75 (1995)43;
7) R. Hytry, et.al, J. Vac. Sci. A 11(15), September/October 1993, P2508;
8) U.S. Pat. No. 4,335,677;
9) U.S. Pat. No. 3,974,306;
10) U.S. Pat. No. 5,567,268;
11) U.S. Pat. No. 5,585,176;
12) U.S. Pat. No. 5,902,675;
13) U.S. Pat. No. 6,436,252;
14) U.S. Pat. No. 6,767,436;
15) U.S. Pat. No. 7,052,736;
16) U.S. Pat. No. 7,629,031;
17) U.S. Pat. No. 7,608,151;
18) U.S. Pat. No. 5,224,441.

### FIELD OF INVENTION

The invention is related to methods and apparatus facilitating functional material deposition on the internal surface of work pieces, more specifically to designs of adding permanent magnet array assembly to generate magnetic field inside the work pieces in order to improve the uniformity, deposition rate, better adhesion and reduce the process temperature for the plasma enhanced chemical vapor deposition (PECVD) on the internal surface of tubular work piece.

### BACKGROUND ART

Many techniques have been developed in order to improve the surface mechanical properties, such as, wear, erosion, corrosion, friction, and biocompatible properties, of a work piece. These include typically two techniques:
1. Surface treatment with plasma only, such as Beam Ion Implantation (BII) and Plasma Immersion Ion Implantation (PIII). No material is deposited onto the work piece. This method can only affect the top surface of the work piece, and the treated depth is generally believed to be too thin for many applications.
2. Functional coating the surface of a work piece. The widely used methods includes:
   1) Physical Vapor Deposition (PVD);
   2) Chemical Vapor Deposition (CVD);
   3) Plasma Enhanced Chemical Vapor Deposition (PECVD);

Coating the internal surface of a work piece is more important as there are many applications that require the properties of the internal surface of the work piece to be modified and improved. For example, in the case, such as aircraft landing gear hydraulic cylinders, automotive engine cylinder liners, military gun barrels, and pipes for transmitting petroleum and chemical products, better wear, erosion, corrosion, and friction properties can generally be achieved via hard internal-surface coating, such as CrN, TiN, or DLC. In other cases, functional SiO2, TiO2, or DLC thin film need to be coated onto the internal wall of a fine tube, or implanted medical devices to enhance antivirus, antibacterial, and biocompatible properties.

PECVD process has relatively large deposition rate, lower process temperature (<200 C, or at room temperature), large scale, and most of all, all the surface exposed to the reactive gas can be coated evenly. Therefore it is generally considered as a 3D coating process, and widely used in industry applications. It is especially useful for coating the internal surface of a work piece.

Malik et al. developed a PECVD technique to deposit DLC films onto internal surface of a tube. In order to maintain the discharge in a small tube, they inserted a ground electrode into the tube center so that a hollow glow discharge can be generated and sustained. However, when the tube diameter becomes even smaller and the length becomes even longer, it is getting more difficult to sustain the hollow glow discharge.

A microwave antenna was also applied into the tube to enhance the plasma by Baba and Hatada et.al in another attempt to coating the internal surface of a tube using PECVD technology. They also placed an electromagnetic coil outside the tube with high voltage applied onto the tube. By moving the coil location, they were able to generate plasma inside tubes and control the deposition rate locally. However, the tube can only be coated one section at a time due to the limitation of localized plasma generated only at the coil location.

In this invention, to take the advantage of both PECVD process and the magnetic field impact on plasma, magnet array assembly is employed outside/inside a tube to further enhance the plasma density for PECVD process. With the help of the magnet array assembly, higher deposition rate, lower process temperature, better adhesion and better uniform deposition rate, can be obtained for coating the internal surface of a work piece.

### SUMMARY OF THE INVENTION

The present invention includes, at least, a permanent magnet array assembly embodied on a PECVD system for internal wall coating of work piece with high aspect ratio and/or complicated internal structures such as pipe and tube. The method includes: isolate the work piece and use it as effective vacuum chamber; input gas precursor and/or gas mixture for designed internal coating layer structure; apply either pulse DC or RF energy and use the permanent magnet array assembly to enhance the glow discharge in the whole or only certain portion of the work piece; to efficiently deposition functional layer(s) on the internal wall of the work piece.

The design of adding the permanent magnet arrays assembly in the present apparatus is of importance. Firstly, the magnetic field restricts the path of free electron within the glow discharge and effectively increase the efficiency of ionization within the glow discharge and allow the sustain of the glow discharge under high gas pressure of precursor (or process gas mixture) with the possibility of sustain glow discharge even under atmosphere pressure to allow high rate deposition and lower process temperature. The sustaining of the glow discharge at lower vacuum or even at atmosphere pressure reduce overall cost of ownership of the apparatus while still retaining the quality of the internal coating with higher deposition rate. Secondly, the magnet array assembly can be rotated or oscillate around the longer axial of the work piece with dwell time optimized for special purpose. For example, the dwell time can be optimized for uniformity coating thickness along the work piece in one case, while in the other case, the deposition thickness can be specified at particular location for the purpose of enhance the functionality and performance of the work piece.

In this invention, there are two types of designs for the permanent magnet array assembly: one is implemented outside of the work piece; the other is put inside of the work piece. The type of permanent magnet array assembly for use outside of the work piece is particularly useful for the work piece with small internal wall diameter such as the capillary tube used within the medical instruments or the microfluidic devices. For the work piece with large enough internal wall diameter, the magnet array assembly design for the internal use could be better. Of course, when the situation is allowed, both types of the permanent magnet array assemblies can be implemented at the same time.

### BRIEF DESCRIPTION OF THE DRAWINGS

FIG. 1 illustrates one of the embodiments of the coating apparatus set up for current invention.

FIG. 2 illustrates a second embodiment of the coating apparatus set up for the current invention.

FIG. 3 illustrates one embodiment of the principle of permanent magnet array design for current invention.

FIG. 4A and FIG. 4B illustrates the principle of the Halbach permanent magnet array arrangement in the prior art.

FIG. 5 illustrates the embodiment of implementing of the principles of the magnet array design into the apparatus of current invention.

FIG. 6 illustrates another embodiment of implementing of the principles of the magnet array design into the apparatus of current invention.

FIG. 7 illustrates another embodiment of implementing of the principles of the magnet array designs into the apparatus of current invention.

FIG. 8 illustrates an embodiment of the coating apparatus with the magnet assembly inserted into the work piece.

FIG. 9 illustrates another embodiment of the coating apparatus with the magnet assembly inserted into the work piece.

### DETAILED DESCRIPTION

The following description is provided in the context of particular applications and the details, to enable any person skilled in the art to make and use the invention. However, for those skilled in the art, it is apparent that various modifications to the embodiments shown can be practiced with the generic principles defined here, and without departing the spirit and scope of this invention. Thus, the present invention is not intended to be limited to the embodiments shown, but is to be accorded the widest scope consistent with the principles, features and teachings disclosed here.

The present invention relates to method and apparatus design to facilitate the disposition of the functional coating on the internal wall of the work piece with particularly emphasis on implementing the permanent magnet array assembly to enhance the glow discharge during PECVD coating. Depending on the size of the permanent magnet array assembly relative to the work piece, the glow discharge can be generated either through the whole work piece or localized only in a portion of the work piece at any given time.

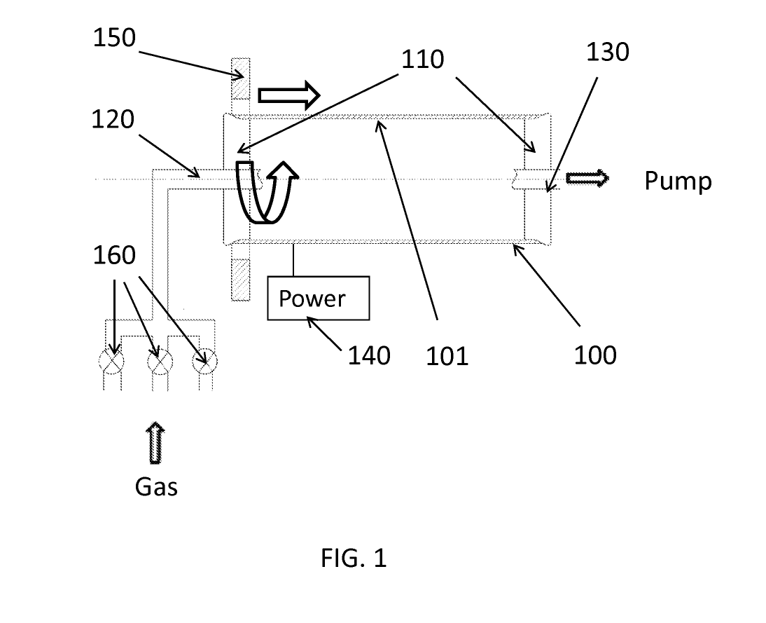

With reference of the FIG. 1, a conductive and non- or low-magnetic work piece 100, with an internal wall 101 is connected from both ends by end components 110, which are electrically insulated from the work piece 100. The deposition working chamber consists the work piece 100 and end components 110. On one of the end component 110, there is a gas inlet 120 connecting to the external gas supply with several gas control devices 160 such as mass flow controller (MFC) for accurate control of the gas input into the working chamber. On the other end component 110, there is a gas outlet 130, which could connect to vacuum pump. When the process requires the pressure of the working chamber below the atmosphere pressure, the end components 110 can be made of the vacuum tight sealing components. The conductive work piece 100 is connected to external DC pulse power supply 140 to allow negative bias to add onto the work piece 100 to assist ignition and sustain the glow discharge while allowing the ion bombardment or/and implantation of the internal wall 101 of the work piece whenever the process is needed. The end components 110 are grounded to form an electrical close loop for the DC pulse power supply. The permanent magnet array assembly 150, which will be illustrated further in the following context, is placed outside of the work piece 100 to assist the glow discharge igniting and sustaining. The permanent magnet array assembly 150 can fully or partially circularly rotate around the central axial of the work piece for improving coating efficiency, uniformity and/or tuning local coating thickness. When the thickness of the magnet array assembly is smaller than the length of the work piece, the permanent magnet array assembly 150 can also move along the center axial of the work piece. The presence of the permanent magnet assembly 150 enhances the glow discharge, which could increase the efficient of PECVD process, enable PECVD at higher process pressure, and/or improve the coating quality.

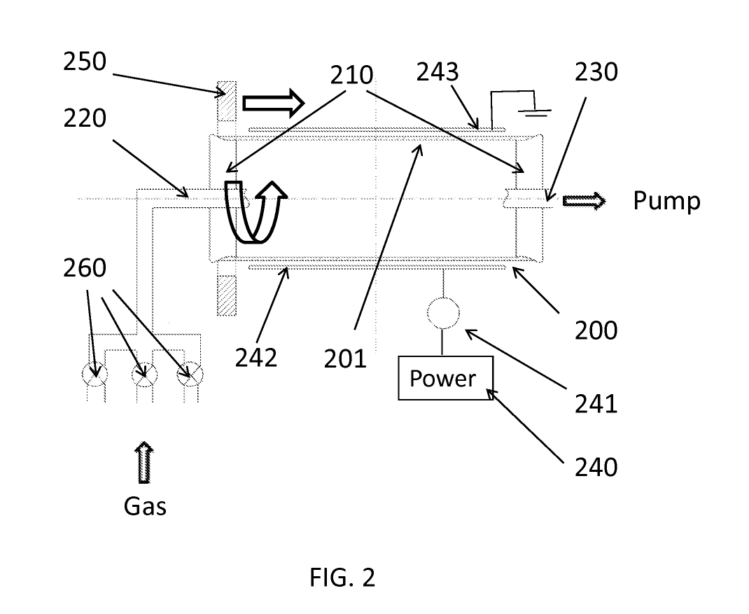

With reference of the FIG. 2, a non-conductive work piece 200, with an internal wall 201 is connected from both ends by end components 210. The deposition working chamber consists the work piece 200 and end components 210. On one of the end component 210, there is a gas inlet 220 connecting to the external gas supply with several gas control devices 260 such as mass flow controller (MFC) to allow accurate control of the gas input into the working chamber. On the other end component 210, there is a gas outlet 230, which could connect to vacuum pump if needed. When the process requires maintaining the pressure of the working chamber below the atmosphere pressure, the end components 210 can be made of vacuum tight sealing components. There are two electrodes 242 and 243 locating outside of the work piece, which acts as radio frequency (RF) electrodes/antennas to allow the energy coupled into the glow discharge inside the working chamber. One piece of the electrode 242 is connected to RF matching box 241 and external RF power 240, while the other piece of the electrode 243 is grounded. The length of the electrodes could be the same as or slight shorter than the length of the work piece 200. The permanent magnet array assembly 250, which will be illustrated further in the following context, is placed outside of the work piece 200 to assist the glow discharge igniting and sustaining. The permanent magnet array assembly 250 can fully or partially circularly rotate around the central axial of the work piece for enhancing the PECVD process. When the thickness of the magnet array assembly is smaller than the length of the work piece, the permanent magnet array assembly 250 can also move along the center axial of the work piece. The presence of the permanent magnet assembly 150 enhances the glow discharge, which could increase the efficient of PECVD process, enable PECVD at higher process pressure, and/or improve the coating quality.

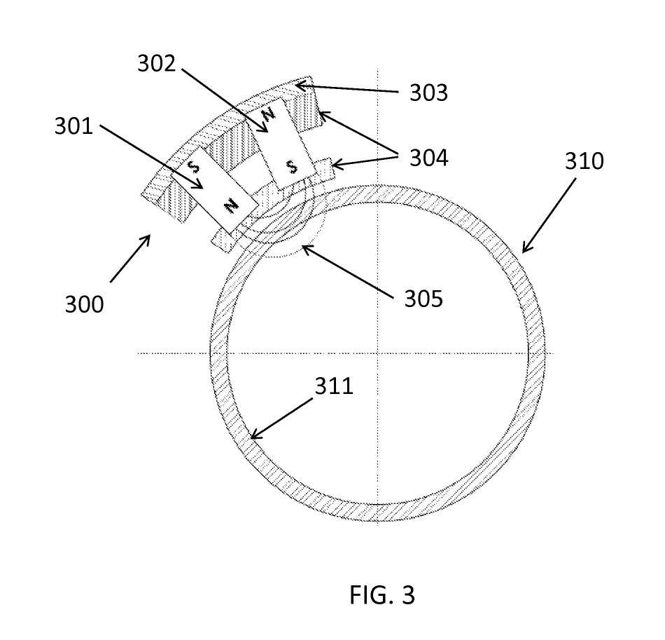

With reference of the FIG. 3, a cross section view (perpendicular to the long axial of the work piece) of portion of the permanent magnet array segment, which may be embodied in the present apparatus for internal wall coating, is shown. In this illustration, the permanent magnet array segment 300 is placed adjacent and outside the work piece 310 with an internal wall 311. The magnet segment 300 consists of adjacent permanent magnet bars 301 and 302, support insulator 304 and soft magnetic rail 303. The magnetization directions of the permanent magnet bars 301 and 302 aim toward the work piece with northern and southern poles of the adjacent magnet bars pointing towards the opposite directions so that the magnetic fringe field 305 can penetrate through the wall of the work piece to assist the PECVD process. The distance between the adjacent magnet elements can be optimized based on magnetic strength of bar permanent magnets as well as the wall thickness and material properties of the work piece 310.

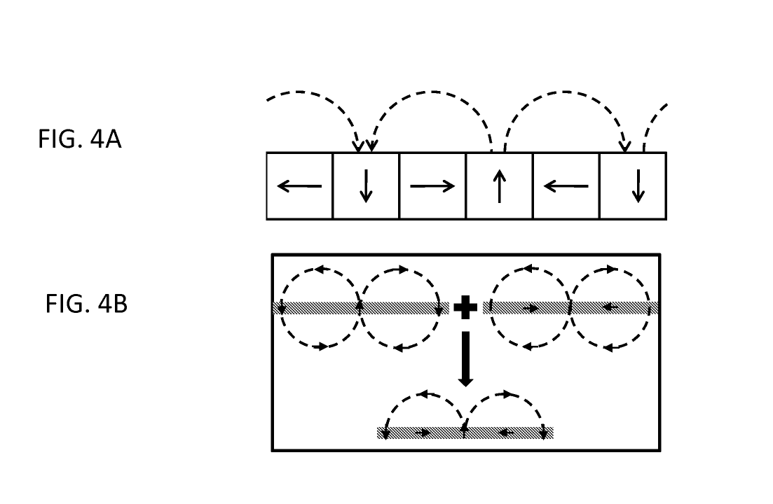

As shown in FIG. 4A, a typical Halbach array is illustrated. In Halbach array, adjacent magnets are arranged with their magnetization directions alternating in directions perpendicular with each other. As shown in FIG. 4B, the field above the plane is in the same direction for both structures, but the field below the plane is in opposite directions. Such arrangement of permanent magnets will reinforce the magnetic field on one side of the array while cancel the field to near zero on the other side, which is called “a one-sided flux”. The advantages of one sided flux distribution are twofold:
1. The field is twice as large on the side on which the flux is confined;
2. No stray field is produced on the opposite side. This helps with field confinement.

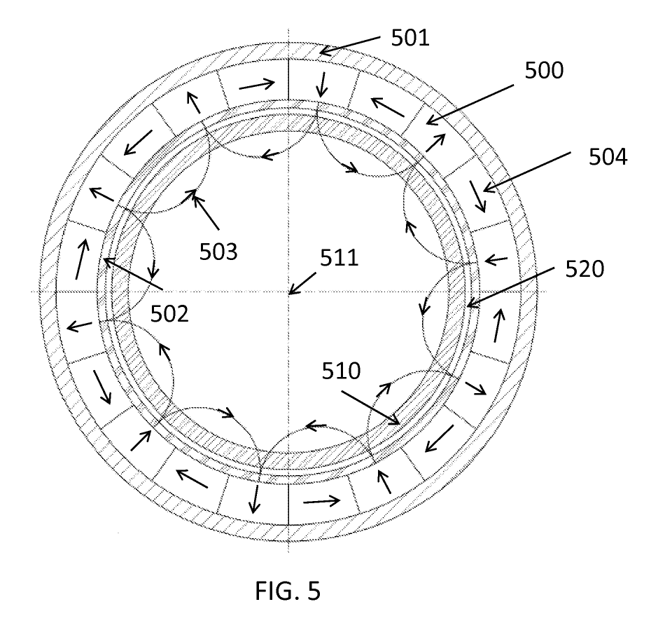

FIG. 5 illustrates an embodiment of a permanent magnet ring assembly 500 that may be implemented in PECVD apparatus of present invention. Although the exact details of the magnet ring assembly can vary, there are at least three basic components in this assembly, namely outer soft magnetic ring 501, the non-magnetic support part(s) 502, the field generating magnet-assembled ring 504, which is sandwiched between 501 and 502. Within magnet assembled ring 504, all magnets are made of permanent magnetic materials, such as NdFeB, SmCo, AlNiCo. Each magnet element is engineered in a particular shape, eg. fan shape, to match the local contour of external wall of the work piece 510. All the magnets are closely packed and arranged according to the principle of the Halbach array in this embodiment so that big enough magnetic flux 503 can be generated and penetrate through the wall of the work piece 510 and help to enhance the glow discharge during PECVD process. All the magnets are assembled into the pre-design location with the help of the non-magnetic supporting element 502. The exact materials, arrangement and sharp of the supporting element 502 can vary. A soft magnetic shield in circular shape 501 is used to cover the outmost surface of the ring assembly to form a magnetic close loop to eliminate the entire magnetic fringe field outside the soft magnetic ring 501. Although the magnet assembly 500 in FIG. 5 is configured via the principle of the Halbach as shown in FIG. 4, it can also be assembled using the arrangement and magnet design principle shown in FIG. 3, which serves the same purpose of generating magnetic field 503 seen in FIG. 5. Between the work piece 510 and magnet assembly 500, there is a gap 520, which enables the magnet assembly 500 can move, free of major friction, around the center of the work piece 511 as well as along the long axle of the work piece.

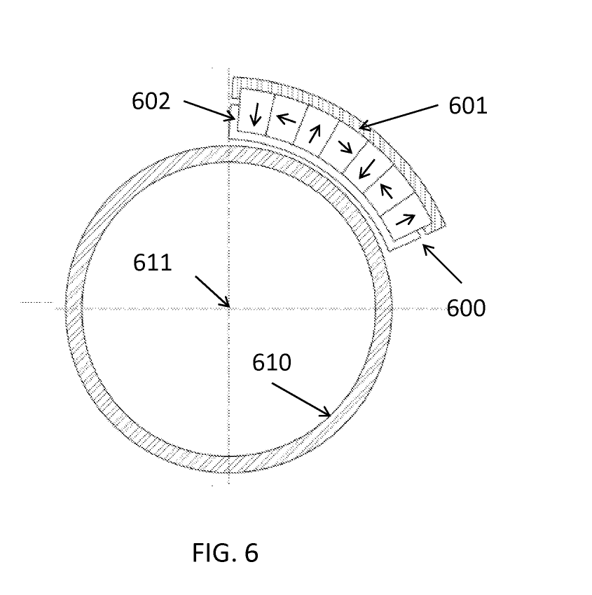

FIG. 6 illustrates an alternative embodiment of a permanent magnet ring assembly 600 that may be implemented in PECVD apparatus of the present invention. The schematic drawing in FIG. 6 is self explanatory. Basically, the magnet assembly is a sector of the magnet assembly shown in FIG. 5, with similar functional non-magnetic supporting part(s) 602 and soft magnetic ring 601 for flux close. Since the magnetic assembly 600 is only cover portion of the surface of the work piece, in order to coat uniform deposit around the whole internal wall of the work piece 610, the magnet assembly has to rotate round the center axle of the work piece 611. Although there is only one sector is shown in FIG. 6, multiple sectors can be used to give the balance between the mechanical movement and the number of magnet assemblies for cost saving purpose.

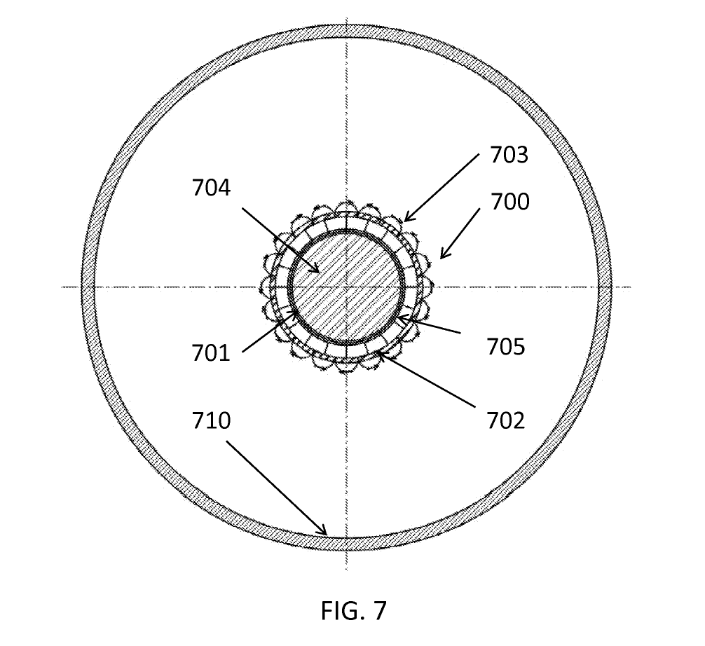

FIG. 7 illustrates an embodiment of a permanent magnet ring assembly 700 that may be implemented in PECVD apparatus of the present invention. Noticeably, the magnet ring assembly 700 is placed inside the work piece 710. This arrangement is of importance when the work piece is made by materials with high magnetic moment or the wall thickness of the work piece is too thick for the externally arranged magnet assembly as shown in FIG. 5 and FIG. 6 to easily generate large enough magnetic field to penetrate through the wall of the work piece and assist PECVD process. The magnet assembly 700 consists of a center support rod 704 covered with a surface ring 701 made by soft magnetic materials, such as soft Fe, magnet-assembled ring 705 and non-magnetic supporting structure(s) 702. The permanent magnet elements within magnet-assembled ring 705 are arranged based on principle shown in either FIG. 3 or FIG. 4. The purpose of the magnet assembly 700 is to generate the magnetic flux 703 around it and into the space of the internal work piece 710.

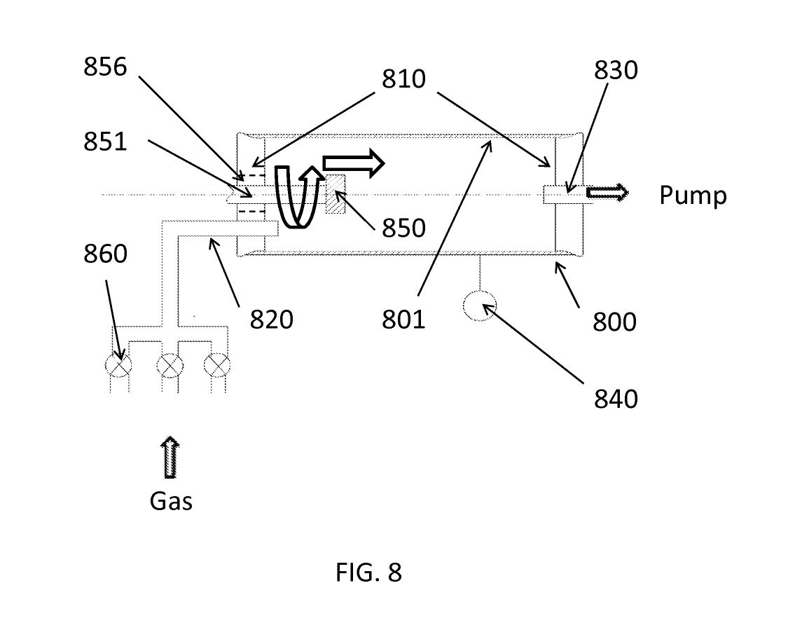

With reference of the FIG. 8, a conductive and non- or low-magnetic work piece 800, with an internal wall 801 is connected from both ends by end components 810, which is electrically insulated from the work piece 800. The deposition working chamber consist the work piece 800 and end components 810. On one of the end component 810, there is a gas inlet 820 connecting to the external gas supply with several gas control devices 860 such as mass flow controller (MFC) to allow accurate control of the gas input into the working chamber. On the other end component 810, there is a gas outlet 830, which can connect to vacuum pump if needed. When the process requires maintaining the pressure of the working chamber below the atmosphere pressure, the end components 810 can be made of vacuum tight sealing components. The conductive work piece 800 is connected to external DC pulse power supply 840 to allow negative bias to add onto the work piece 800 to assist ignition and sustain the glow discharge while allowing the ion bombardment or/and implantation of the internal wall 801 of the work piece whenever the process is needed. The end components 810 are grounded to form an electrical close loop for the DC pulse power supply. The permanent magnet assembly 850, which has been illustrated in details in FIG. 7, is placed inside of the work piece 800 to assist the glow discharge igniting and sustaining. The permanent magnet assembly 850 can fully or partially circularly rotate around the central supporting rod 851 for improving coating uniformity. The central supporting rod 851 can move smoothly through the end component 810 via mechanical bearing component 856, which is am existing know-how from prior art. To maintain the vacuum seal, the mechanical bearing component 856 can be bearings with magnetic fluidic seal. When the length of the magnet array is smaller than the length of the work piece, the permanent magnet array 850 can also move along the center axial of the work piece.

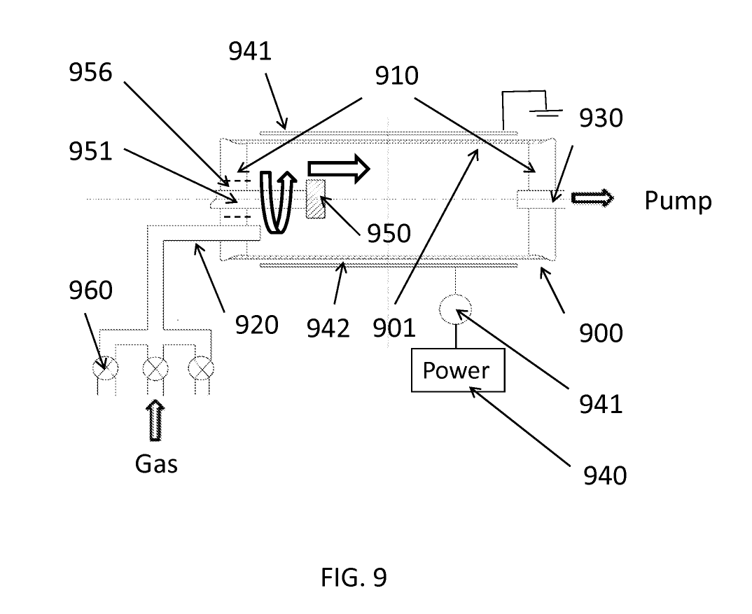

With reference of the FIG. 9, a non-conductive work piece 900, with an internal wall 901 is connected from both ends by end components 910. The deposition working chamber consist the work piece 900 and end components 910. On one of the end component 910, there is a gas inlet 920 connecting to the external gas supply with several gas control devices 960 such as mass flow controller (MFC) to allow accurate control of the gas input into the working chamber. On the other end component 910, there is a gas outlet 930, which can connect to vacuum pump. When the process requires the pressure of the working chamber below the atmosphere pressure, the end components 910 can be vacuum tight sealing components. There are two electrodes 942 and 941 locating outside of the work piece, which acts as radio frequency (RF) electrodes to allow the energy coupled into the glow discharge inside the working chamber. One piece of the electrode 942 is connected to RF matching box 941 and external RF power 940, while the other piece of the electrode 941 is grounded. The length of the electrodes could be the same as or slight shorter than the length of the work piece. The permanent magnet-array assembly 950, which has been illustrated in details in FIG. 7, is placed inside of the work piece 900 to assist the glow discharge igniting and sustaining. The permanent magnet array assembly 950 can fully or partially circularly rotate around the central supporting rod for improving coating uniformity. The central supporting rod 951 can move smoothly through the end component 910 via mechanical bearing component 956, which is an existing know-how from prior art. To maintain the vacuum seal, the mechanical bearing component 956 can be made of bearings with magnetic fluidic seal. When the length of the magnet array is smaller than the length of the work piece, the permanent magnet array 950 can also move along the center axial of the work piece.

What is claimed is:

1. An apparatus for deposition of functional coating(s) on the internal surface of work pieces using magnetically enhanced PECVD process, which includes:
a working chamber consisting the work piece and the end components
a gas inlet with gas control mechanism as well as a gas outlet
a power source, which can be either DC pulse or RF power supply for energy input into the glow discharge formed inside the working chamber
at least one magnet assembly, which generates the magnetic field to enhance the PECVD process

2. The working chamber in claim 1, can be a sealed vacuum chamber. A vacuum tide seal mechanism is implemented between the work piece and the end components.

3. The work piece in claim 1 can be conductive. A DC pulse power supply is connected to the conductive work piece as energy source for the glow discharge.

4. The work piece in claim 1 can be non-conductive. A RF power supply is used as energy source for the glow discharge in the non-conductive work piece. Two RF electrodes made by conductive materials connected to the RF power supply are used outside the work piece as RF antennas.

5. The size of the magnet assembly in claim 1 can be the same length as, or shorter or longer than the work piece.

6. The magnet assembly as said in claim 1 can be arranged multiple times along the work piece.

7. The magnet assembly as said in claim 1 can be arranged multiple times around the cross section of the work piece.

8. The magnet assembly as said in claim 1 can be located outside the work piece.

9. The magnet assembly as said in claim 1 can be located inside the work piece. A center support rod is used to insert the magnet assembly into the working piece. The center support rod as said can have a vacuum seal mechanism with the end component so that the vacuum in working chamber is maintained.

10. The magnet assembly as said in claim 1 can be located outside the work piece as well as inside the work piece at the same time.

11. The magnet assembly as said in claim 1 can rotate around the center axle of the work piece.

12. The magnet assembly as said in claim 1 can also move along the work piece.

13. The magnet assembly as said in claimed 1 can dwell at a particular location at a specified time period based on the requirements of the local coating thickness or global coat uniformity.

14. The magnet assembly as said in claim 1 consists at least:
A Soft magnetic part(s)
A Non-magnetic support part(s)
A field generating magnet-assembled part

15. The field generating magnet-assembled part as said in claim 14, is composed by permanent magnets array, which is made of NdFeB, or SmCo, or AlNiCo;

16. The said soft magnet part of claim 14 is made of Fe, or NiFe, CoFe or CoNiFe.

17. The field generating magnet-assembled part as said in claim 14, can be in a ring-shape or a portion of ring shape such as a fan-shape. If it is a portion of the ring, multiple portions can be used outside the working piece.

18. When the magnet assembly is used outside the working piece, the soft magnetic part, as said in claim 14, can be located at the outmost of the entire magnet assembly while the field generating magnet-assembled part sandwiched between the soft magnetic and non-magnetic support parts.

19. When the magnet assembly is used inside the working piece, the non-magnetic support parts, as said in claim 14, can be located at the outmost of the entire magnet assembly while the field generating magnet-assembled part sandwiched between the non-magnetic support parts and soft magnetic part, which is attached on center support rod.

20. The field generating magnet-assembled part, as said in claim 14 consists of an array of magnets arranged with the magnetization directions of adjacent magnets alternating in directions perpendicular with each other to reinforce said magnetic field on one side of the said array while cancel said magnetic field to near zero on the other side.

21. The field generating magnet-assembled part as said in claim 14 consists an array of magnets arranged with the magnetization directions of adjacent magnets alternating in directions parallel to each other but with opposite magnetic polarization, which points towards the inside wall of the work piece.
